(19) United States
(12) Patent Application Publication
(10) Pub. No.: US 2014/0361353 A1
(43) Pub. Date: Dec. 11, 2014

(54) SEMICONDUCTOR DEVICE AND METHOD FOR MANUFACTURING THE SAME

(71) Applicants: Haizhou Yin, Poughkeepsie, NY (US); Huilong Zhu, Poughkeepsie, NY (US); Keke Zhang, Liaocheng (CN)

(72) Inventors: Haizhou Yin, Poughkeepsie, NY (US); Huilong Zhu, Poughkeepsie, NY (US); Keke Zhang, Liaocheng (CN)

(73) Assignee: The Institute of Microelectronics, Chinese Acadamy of Science

(21) Appl. No.: 14/357,572

(22) PCT Filed: Jul. 18, 2012
(86) PCT No.: PCT/CN2012/078784

§ 371 Date: May 11, 2014

(30) Foreign Application Priority Data
Jul. 3, 2012 (CN) 201210229434.X

(51) Int. Cl. H01L 29/66; H01L 29/423; H01L 21/28

(52) U.S. Cl. CPC H01L 29/66545; H01L 21/28114; H01L 29/66492; H01L 29/42376
USPC 257/288; 438/305

(57) ABSTRACT

The present application discloses a method for manufacturing a semiconductor device, comprising: forming a T-shape dummy gate structure on the substrate; removing the T-shape dummy gate structure and retaining a T-shape gate trench; filling successively a gate insulation layer and a metal layer in the T-shape gate trench, wherein the metal layer forms the T-shape metal gate structure. According to the semiconductor device manufacturing method disclosed in the present application, the overhang phenomenon and the formation of voids are avoided in the subsequent metal gate filling process by forming a T-shape dummy gate and a T-shape gate trench, and the device performance is improved.

### CROSS-REFERENCE TO RELATED APPLICATION

This application claims priority to the Chinese Patent Application No. 201210229434.X, filed on Jul. 3, 2012, entitled “semiconductor device and method for manufacturing the same”, which is incorporated herein by reference in its entirety.

### TECHNICAL FIELD

The present disclosure relates to a semiconductor device and a method for manufacturing the same, and in particular, to a semiconductor device manufacturing method, in which voids are not formed in the metal gate, and a semiconductor device manufactured using the same.

### BACKGROUND

With the scaling of MOSFET feature size, the requirements for the gate insulated isolation effect and the control ability of gate to channel region gets higher and higher. The conventional silicon oxide insulation layer could not continuously provide enough insulated isolation when its thickness becomes thinner gradually, while the polysilicon gate could not precisely control the work function to adjust the device threshold voltage. Currently the high-k metal gate structure, which uses high-k materials as gate insulation layer and filled metal materials as gate conductive layer, becomes the mainstream in MOSFET. Because the high-k materials can easily react at high temperatures or under ion bombardment, the development of the gate-first process, in which the gate stack structure is deposited first and then the S/D region is formed by ion implantation and activation annealing, is restricted. The gate-last process, in which a dummy gate stack is deposited first and the S/D region is formed by ion implantation, and then the dummy gate is etched to form gate trench and the gate stack is deposited in the gate trench, gradually dominates.

However, with further decrease in size, the aspect ratio of the gate trench becomes bigger continuously for smaller device. The gate trench filling in gate-last process becomes a major bottleneck in process development. As exposed in the U.S. 2012/012948 A1, because the width of the gate trench is too narrow compared to its depth, the first layer metal materials will form a “overhang” at the top edge of the gate trench when depositing the work function adjusting layer/metal blocking layer, i.e. the first metal layer will form a local protrusion that is toward the gate trench center and beyond the gate spacer at the top edge. The second layer metal materials will close and end deposition filling earlier due to this local protrusion in the subsequent metal filling layer deposition, and accordingly form voids caused by incompletely filling in the middle and bottom parts. These voids cause unnecessary increase in metal gate resistance and lower the device performance.

### SUMMARY OF THE DISCLOSURE

From the above, the purpose of the present disclosure is to provide a semiconductor device manufacturing method, in which voids are not formed in the metal gate, and a semiconductor device manufactured using the same.

According to one aspect of the present disclosure, a method for manufacturing a semiconductor device is provided, comprising: forming a T-shape dummy gate structure on the substrate; removing the T-shape dummy gate structure and retaining a T-shape gate trench; filling successively a gate insulation layer and a metal layer in the T-shape gate trench, wherein the metal layer forms the T-shape metal gate structure.

The steps of forming the T-shape dummy gate structure further comprise: forming a first dummy gate layer and a second dummy gate layer on the substrate; selectively etching the first dummy gate layer to make the remaining width of the first dummy gate layer less than the remaining width of the second dummy gate layer and to constitute the T-shape dummy gate structure.

After the second dummy gate layer is formed and before the first dummy gate layer is selectively etched, it also comprises etching the second dummy gate layer and the first dummy gate layer to form a dummy gate structure with equal width on top and bottom.

The materials for the first dummy gate layer differ from the materials for the second dummy gate layer.

The materials for the first and/or the second dummy gate layers are selected from one of polycrystalline silicon, polycrystalline SiGe, amorphous silicon, silicon oxide, silicon nitride, silicon oxynitride and amorphous carbon, or any combination thereof.

Before the first dummy gate layer is formed, it also comprises forming an oxide liner on the substrate.

After the second dummy gate layer is formed and before the first dummy gate layer is selectively etched, it also comprises forming a dummy gate cap layer on the second dummy gate layer.

The selective etching comprises dry etching and/or wet etching.

After the T-shape dummy gate structure is formed and before the T-shape dummy gate structure is removed, it also comprises: forming a first gate spacer on the T-shape dummy gate structure and forming a lightly doped S/D extension region and/or a halo-S/D doped region on the substrate on both sides of the first gate spacer.

After the lightly doped S/D extension region and/or the halo-S/D doped region are formed, it also comprises: forming a second gate spacer on the first gate spacer, forming an S/D heavily doped region on the substrate on both sides of the second gate spacer, and forming an S/D contact layer in/on the S/D heavily doped region.

After the T-shape dummy gate structure is formed and before the T-shape dummy gate structure is removed, it also comprises forming an interlayer dielectric layer on the substrate and planarizing the interlayer dielectric layer until the T-shape dummy gate structure is exposed.

The planarization steps further comprise: performing a first planarizing to expose the dummy gate cap layer, and performing a second planarizing to expose the second dummy gate layer.

The metal layer comprises a work function adjusting layer and a metal gate filling layer.

The gate insulation layer comprises high-k materials.

According to another aspect of the present disclosure, a semiconductor device is also provided, comprising: a substrate, a gate insulation layer on the substrate, a T-shape metal gate structure on the gate insulation layer, and an S/D region on both sides of the T-shape metal gate structure.

According to the semiconductor device manufacturing method disclosed in the present application, the overhang phenomenon and the formation of voids are avoided in the subsequent metal gate filling process by forming a T-shape dummy gate and a T-shape gate trench, and the device performance is improved.

### BRIEF DESCRIPTION OF THE DRAWINGS

The technical solution of the present disclosure is described in detail with reference to the following attached drawings, in which:

FIGS. 1-11 are schematic cross-sectional views of various stages for manufacturing the semiconductor device according to the present disclosure.

### DETAILED DESCRIPTION

The characteristics of the technical solutions and the technical effect of the present disclosure will be described in detail with reference to the attached drawings in combination with the exemplary embodiments to disclose a semiconductor device manufacturing method, in which voids are not formed in the metal gate, and a semiconductor device manufactured using the same. It should be noted that similar reference numerals denote similar structures in the drawings. The terms of first, second, above, below, etc. can be used to describe various device structures or process steps. The description does not imply the relationship of space, order, or hierarchy between device structures or process steps unless otherwise indicated.

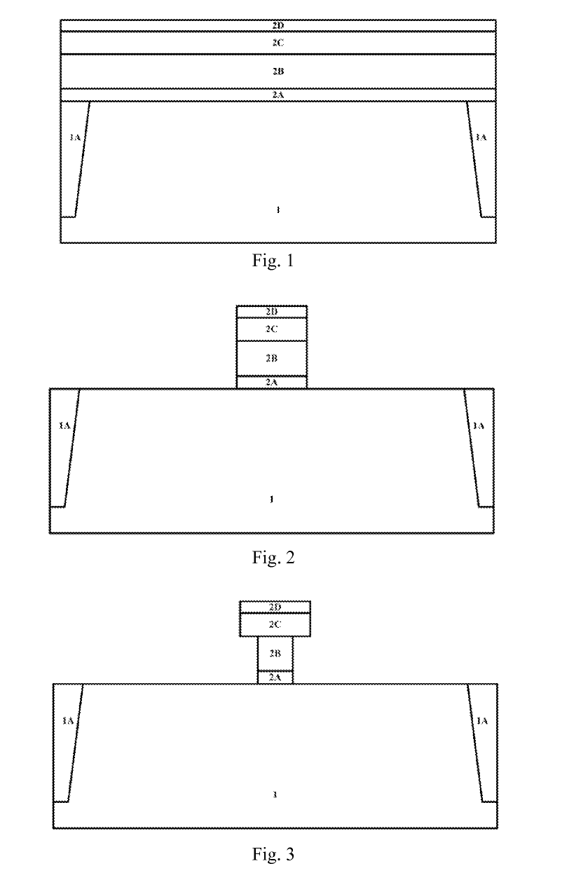

FIGS. 1-11 are schematic cross-sectional views of various stages for manufacturing the semiconductor device according to the present disclosure.

As illustrated in FIG. 1, the stack of the dummy gate material layer is formed successively on the substrate 1. The substrate 1 is provided, such as silicon-based materials comprising bulk silicon (Si), silicon on insulator (SOI), SiGe, SiC, strained silicon, silicon nanotubes, etc. In addition, the substrate 1 can also be other semiconducting materials such as Ge, GeOI, SiGe, Group III-V compound, Group II-VI compound. Preferably, bulk silicon or SOI can be selected as the substrate 1 in order to be compatible with CMOS processes. Preferably, an insulation region 1A constituted of oxide materials corresponding to the substrate 1 (such as insulation materials silicon oxide, etc.) is formed, for example, a shallow trench insulation (STI) 1A is formed by etching and deposition on the substrate 1, where STI 1A surrounds and defines the device active region. As illustrated in FIG. 1, an optional oxide liner 2A, a first dummy gate layer 2B, a second dummy gate layer 2C, and an optional dummy gate cap layer 2D are deposited sequentially on the substrate 1 (in the active region) using conventional methods such as LPCVD, HDPCVD, ALD, MBE, cathode-ray deposition, sputtering, ion beam deposition, MVPECV, RFPECVD, etc. The oxide liner 2A is silicon oxide with an exemplary thickness of about 1˜3 nm, and is used to protect the surface of the substrate channel region in the subsequent etching process to avoid over etching of the channel region and decrease in device performance caused by increased surface defect density. The oxide liner 2A can be omitted. The material of the first dummy gate layer 2B is different from that of the second dummy gate layer 2C, and thus the etching rates is different in the subsequent etching. Specifically, the etching rate of the first dummy gate layer 2B may be greater than the etching rate of the second dummy gate layer 2C to form a T-shape dummy gate structure. Specifically, the first dummy gate layer 2B can be polycrystalline SiGe, and the second dummy gate layer 2C can be polycrystalline silicon. In addition, other materials can also be used. For example, the first/second dummy gate layers 2B/2C can be amorphous carbon/polycrystalline silicon, polycrystalline SiGe/amorphous silicon, amorphous silicon/silicon oxide, polycrystalline silicon/silicon oxide, silicon nitride/polycrystalline silicon, silicon nitride/silicon oxide, polycrystalline SiGe/silicon nitride, polycrystalline SiGe/silicon oxide, etc., as far as the materials for the two neighboring layers in 2A, 2B, 2C, 2D are different. Preferably, the dummy gate cap layer 2D can be harder materials such as silicon nitride, silicon oxynitride, diamond-like amorphous carbon (DLC), etc., to serve as hard mask in etching the dummy gate stack structure later to protect the lower softer materials. If the second dummy gate layer 2C is harder materials itself, the dummy gate cap layer 2D can be omitted. The thickness of layers 2A-2D should be set reasonably according to the morphology requirement of the T-shape dummy gate, not necessarily as exactly illustrated in FIG. 1. For example, the thickness for 2A can be only 1˜3 nm, the thickness for 2B can be 5˜20 nm, the thickness for 2C can be 5˜10 nm, and the thickness for 2D can be 1˜5 nm.

As illustrated in FIG. 2, a dummy gate stack structure having equal width and almost vertical sides is formed by etching layers 2A-2D with conventional etching process, for example, preferably using plasma etching to anisotropically etch respective layers with the photoresist layer as a mask. Preferably, the plasma etching gas is ions that hardly react with respective layers, such as inert gas ions Ar, He, Ne, Kr, Xe (and/or stable fluorides of those inert gas ions). The so-formed dummy gate stack structure 2A/2B/2C/2D has equal width on top and bottom, for example, equal to the device channel width of about 10˜30 nm.

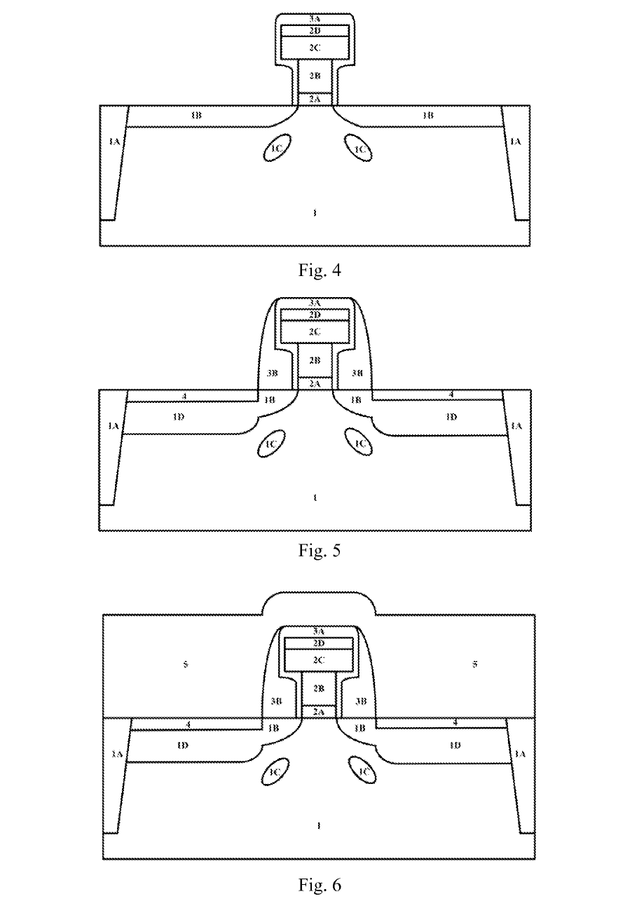

As illustrated in FIG. 3, a T-shape dummy gate structure is formed by selectively etching the oxide liner 2A and the first dummy gate layer 2B. If dry etching is used, the etching rate of the oxide liner 2A and the first dummy gate layer 2B may be greater than the etching rate of the second dummy gate layer 2C and the dummy gate cap layer 2D by adjusting the flow and the components of the etching gas. Specifically, the selective ratio of the etching gas to SiGe/Si in dry etching is dependent on the gas mixture components, microwave frequency, temperature, pressure and the Ge content in SiGe. For example, when oxygen is used as auxiliary gas, the etching rate of fluorine-based gases to SiGe is 4000 nm/min while the etching rate to Si is only 40 nm/min, which means a high selective ratio of 100:1, and Si is substantially not etched in the process of etching SiGe. The etching gases can comprise fluorocarbon-based gases (CF₄, CH₂F₂, CH₃F, CHF₃, C₂HₓF₆₋ₓ, C₃HₓF₈₋ₓ, etc.), fluorine-based gases SF₆, NF₃, XeF, etc., optionally oxidizing gases such as O₂, O₃, Cl₂, NO₂, etc. and diluted inert gases Ar, He, etc. If wet etching is used, suitable wet etching liquids should be selected according to different materials in respective layers. Specifically, the commonly used selective etching liquids for polycrystalline SiGe/polycrystalline Si are buffered solutions HNO₃:H₂O:HF, HF:H₂O₂:H₂O, H₃PO₄—KH₂PO₄—NaOH, and NH₄OH:H₂O₂:H₂O, etc. The solution containing HF has no etching selectivity on silicon oxide, and etches SiGe and the oxide liner at the same time. For the solution not containing HF, HF-based etching liquid may be used to etch the oxide liner. The selective ratio of the NH₄OH:H₂O₂:H₂O solution with a (volume) ratio 1:1:5 is 36:1 for 40% Ge contents (atom number ratio), and 117:1 for 55% Ge contents. In addition, selective etching can be combination of dry etching and wet etching. For example, the first dummy gate layer 2B can be dry etched and the oxide liner 2A can be wet etched hereafter, or part of the first dummy gate layer 2B can be wet etched and the remaining first dummy gate layer 2B and the oxide liner 2A can be dry etched hereafter. In the selective etching steps as illustrated in FIG. 2, the dummy gate cap layer 2D is used to protect the second dummy gate layer 2C and severed as a stop layer in subsequent CMP. Because of the selectivity in etching, the dummy gate cap layer 2D and the second dummy gate layer 2C are not etched or substantially not etched, so that the remaining width of the second dummy gate layer 2C is greater than the remaining width of the first dummy gate layer 2B, and the T-shape dummy gate stack structure as illustrated in FIG. 2 is formed. Specifically, the remaining width of the first dummy gate layer 2B can be ⅔˜⅘ of the remaining width of the second dummy gate layer 2C.

As illustrated in FIG. 4, a first gate spacer and an S/D lightly doped region are formed. The first gate spacer 3A is formed on top and side surfaces of the T-shape dummy gate stack structure by conventional deposition methods such as LPCVD, HDPCVD, ALD, MBE, cathode-ray deposition, sputtering, ion beam deposition, MVPECVD, RFPECVD, etc., the materials of the first gate spacer 3A can be silicon nitride, silicon oxynitride or DLC, and the thicknessis preferably thin enough to be conformal with the T-shape dummy gate stack structure and does not affect the cross-sectional morphology. Specifically, the thickness of the first gate spacer 3A can be only about 1˜3 nm. The lightly doped S/D extension region 1B and/or the halo-S/D doped region 1C are formed on the substrate on both sides of the T-shape dummy gate stack structure by the first S/D doping ion implantation using the first gate spacer 3A as mask. The type, dose, and energy of the doping ions are determined by the MOSFET type and the junction depth, and are not listed herein.

As illustrated in FIG. 5, a second gate spacer, an S/D heavily doped region, and an S/D contact region are formed. The second gate spacer 3B is formed by depositing and etching sidewall materials such as silicon nitride, silicon oxynitride, DLC, etc. on the first gate spacer 3A using the same or similar process. The width of the second gate spacer 3B is greater than the thickness of the first gate spacer 3A, and may be, for example, about 20˜50 nm. The S/D heavily doped region 1D is formed subsequently on the substrate on both sides of the second gate spacer 3B by the second S/D doping ion implantation using the second gate spacer 3B as a mask. A thin metal layer (not shown) is deposited subsequently on the entire device as the precursor of the S/D contact layer, such as Ni, Pt, Co, and combinations thereof. For example, annealing may be performed for 10 s˜5 min at 550˜850° C. so that the thin metal layer reacts with the materials of the substrate 1 in the S/D heavily doped region 1D to form the S/D contact layer 4 with lower resistance. The S/D contact layer 4 is metal silicide when the substrate 1 is silicon-based materials.

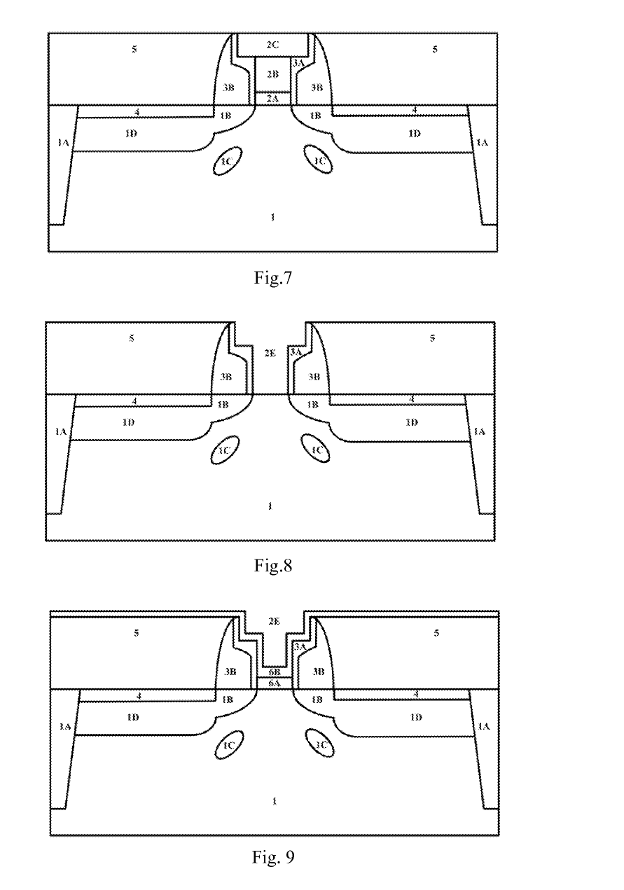

As illustrated in FIG. 6, an interlayer dielectric layer 5 is formed by deposition on the entire device structure. The interlayer dielectric layer (ILD) 5 can be formed with low-k materials by methods such as LPCVD, PECVD, spin coating, spraying, screen printing, etc., where the low-k materials may comprise, but are not limited to, organic low-k materials (such as organic polymers containing aryl or multi-ring), inorganic low-k materials (such as amorphous carbon nitride films, polycrystalline boron nitride films, fluorine-silica glass, BSG, PSG, BPSG), porous low-k materials (such as silsesquioxane (SSQ)-based porous low-k materials, porous silicon dioxide, porous SiOCH, C-doped silicon dioxide, F-doped porous amorphous carbon, porous diamond, porous organic polymers). Preferably, ILD5 is silicon oxide or silicon oxynitride.

As illustrated in FIG. 7, ILD5 and the dummy gate cap layer 2D can be planarized by over etching or CMP until the second dummy gate layer 2C is exposed. The planarization process comprises two steps: firstly, ILD5 is treated by a first CMP or planarization until the dummy gate cap layer 2D is exposed, i.e., the planarization stops at the top surface of the dummy gate cap layer 2D; secondly, the dummy gate cap layer 2D is removed by subsequently changing the grinding fluid or etching media (etching gas or etching fluid) and the planarization stops at the top surface of the second dummy gate layer 2C. In such a case, as illustrated in FIG. 7, the remaining layers 2C and 2B together constitute the T-shape dummy gate structure.

As illustrated in FIG. 8, the T-shape dummy gate structure 2C/2B and the oxide liner 2A are removed by etching and the T-shape gate trench 2E is retained. The dummy gate and the oxide liner 2A are removed and the gate trench 2E is retained by dry process of plasma etching (the etching can be stopped according to specific compound production detection, or can be determined according to the relation between the etching rate, time and film thickness), for example, plasma etching by O, Ar, CF₄, etc., or different etching liquids can be selected for wet etching according to different materials for layers 2C, 2B, and 2A.

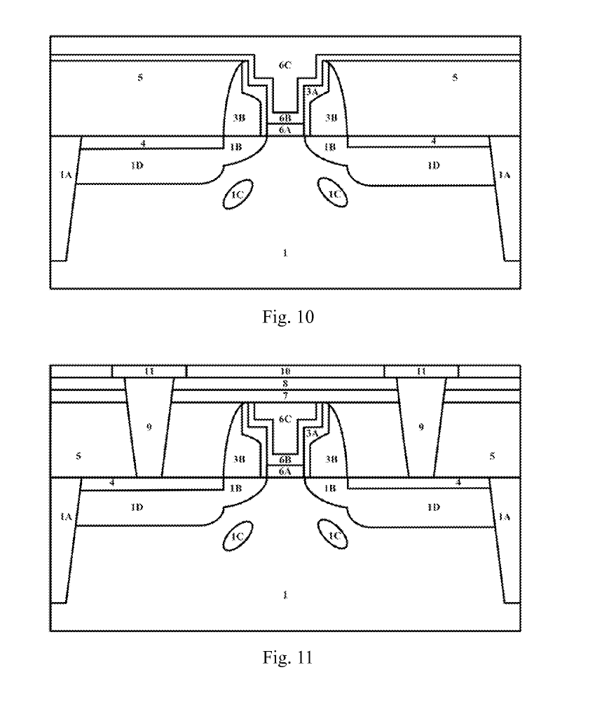

As illustrated in FIG. 9, a gate insulation layer 6A and a work function adjusting layer 6B are formed. The gate insulation layer 6A is formed by depositing high-k materials on the bottom of the gate trench 2E using conventional methods such as LPCVD, HDPCVD, ALD, MBE, cathode-ray deposition, sputtering, ion beam deposition, MVPECV, RFPECVD, etc. The high-k materials comprise, but are not limited to, nitride (such as SiN, AlN, TiN), metal oxide (mainly sub-group and lanthanide metal oxides such as Al₂O₃, Ta₂O₅, TiO₂, ZnO, ZrO₂, HfO₂, CeO₂, Y₂O₃, La₂O₃), perovskite phase oxide (such as PbZrₓTi₁₋ₓO₃ (PZT), BaₓSr₁₋ₓTiO₃ (BST)). Optionally, the gate insulation layer 6A can be deposited not only on the bottom of the gate trench 2E as illustrated in FIG. 9, but also on sidewalls of the gate trench 2E (not shown). Subsequently, the first metal layer 6B is formed by deposition in ILD 5 and the T-shape gate trench 2E as a work function adjusting layer or a metal blocking layer by methods such as sputtering, MOCVD, ALD), etc. The materials for the first metal layer 6B can be TiN, TaN, or combinations thereof, the thickness of which may be selected according to requirements for work function adjusting. It should be noted that the overhang phenomenon will not happen during the deposition of the first metal layer 6B due to the special morphology of the T-shape gate trench.

As illustrated in FIG. 10, the second metal layer 6C is deposited on the first metal layer 6B. The second metal layer 6C is formed on the first metal layer 6B (and further in the gate trench) as a metal gate filling layer with materials such as Ti, Ta, W, Al, Cu, Mo, etc., or combinations thereof, by methods such as sputtering, MOCVD, ALD, etc. Since overhang phenomenon does not happen in deposition of the first metal layer 6B as illustrated in FIG. 9, the second metal layer 6C can be completely filled into the remaining part of the gate trench without forming any voids in the gate, and this ensures that the gate resistance will not increase and the device performance is improved. As illustrated in FIG. 10, the first metal layer 6B and the second metal layer 6C together constitute the T-shape metal gate structure that is conformal with the T-shape gate trench.

Finally, as illustrated in FIG. 11, subsequent processes may be performed. A contact etch stop layer (CESL)7 with materials such as SiN, SiON is deposited on the entire device, an S/D contact hole is formed by depositing the second ILD8 and etching the second ILD8, CESL7, and ILD5, an S/D contact plug 9 is formed by filling metals and/or metal nitrides, lead holes are formed by depositing and etching the third ILD 10, leads 11 are formed by filling metals in the lead holes to form word lines or bit lines of the device, and the production of the device structure is completed. As illustrated in FIG. 11, the final MOSFET device structure may comprise at least the substrate 1, the gate insulation layer 6A on the substrate 1, the T-shape metal gate structure 6B/6C, the S/D region (the S/D extension region 1B, the halo-S/D region 1C) on both sides of the T-shape metal gate structure, the S/D contact layer 4 on the S/D region. The structure and corresponding materials for the rest MOSFET components are described in detail in the above method description and are not listed herein.

According to the semiconductor device manufacturing method disclosed in the present application, the overhang phenomenon and the formation of voids are avoided in the subsequent metal gate filling process by forming a T-shape dummy gate and a T-shape gate trench, and the device performance is improved.

Although the present application has been already illustrated according to the above one or more examples, it will be appreciated that numerous modifications and embodiments may be devised by the skilled in the art without deviating the scope of the present application. Furthermore, it may be devised from the teaches of the disclosure changes suitable for special situation or materials without deviating the scope of the present application. Therefore, objects of the disclosure are not limited to special examples for preferred embodiments, meanwhile structure of the device and manufacture method thereof cover all embodiments fall into the scope of the present application.

1. A method for manufacturing a semiconductor device, comprising:
forming a T-shape dummy gate structure on the substrate;
removing the T-shape dummy gate structure and retaining a T-shape gate trench;
sequentially filling a gate insulation layer and a metal layer in the T-shape gate trench, wherein the metal layer forms the T-shape metal gate structure.

2. The method according to claim 1, wherein the step of forming the T-shape dummy gate structure further comprises:
forming a first dummy gate layer and a second dummy gate layer on the substrate; and
selectively etching the first dummy gate layer so that the width of the remaining first dummy gate layer is less than that of the second dummy gate layer, so as to constitute the T-shape dummy gate structure.

3. The method according to claim 2, wherein after the second dummy gate layer is formed and before the first dummy gate layer is selectively etched, the method further comprises etching the second dummy gate layer and the first dummy gate layer to form a dummy gate structure with equal width on top and bottom.

4. The method according to claim 2, wherein the materials for the first dummy gate layer differ from the materials for the second dummy gate layer.

5. The method according to claim 4, wherein the materials for the first and/or the second dummy gate layers are selected from one of polycrystalline silicon, polycrystalline SiGe, amorphous silicon, silicon oxide, silicon nitride, silicon oxynitride and amorphous carbon, or any combination thereof.

6. The method according to claim 2, wherein before the first dummy gate layer is formed, the method further comprises forming an oxide liner on the substrate.

7. The method according to claim 2, wherein after the second dummy gate layer is formed and before the first dummy gate layer is selectively etched, the method further comprises forming a dummy gate cap layer on the second dummy gate layer.

8. The method according to claim 2, wherein the selective etching comprises dry etching and/or wet etching.

9. The method according to claim 1, wherein after the T-shape dummy gate structure is formed and before the T-shape dummy gate structure is removed, the method further comprises: forming a first gate spacer on the T-shape dummy gate structure and forming a lightly doped S/D extension region and/or a halo-S/D doped region on the substrate on both sides of the first gate spacer.

10. The method according to claim 9, wherein after the lightly doped S/D extension region and/or the halo-S/D doped region are formed, the method further comprises: forming a second gate spacer on the first gate spacer, forming an S/D heavily doped region on the substrate on both sides of the second gate spacer, and forming an S/D contact layer in/on the S/D heavily doped region.

11. The method according to claim 2, wherein after the T-shape dummy gate structure is formed and before the T-shape dummy gate structure is removed, the method further comprises forming an interlayer dielectric layer on the substrate and planarizing the interlayer dielectric layer to expose the T-shape dummy gate structure.

12. The method according to claim 11, wherein the planarizing step further comprises: performing a first planarizing to expose the dummy gate cap layer, and performing a second planarizing to expose the second dummy gate layer.

13. The method according to claim 1, wherein the metal layer comprises a work function adjusting layer and a metal gate filling layer.

14. The method according to claim 1, wherein the gate insulation layer comprises high-k materials.

15. A semiconductor device, comprising: a substrate, a gate insulation layer on the substrate, a T-shape metal gate structure on the gate insulation layer, and an S/D region on both sides of the T-shape metal gate structure.
